(19) United States
(12) Patent Application Publication
(10) Pub. No.: US 2017/0345559 A1
(43) Pub. Date: Nov. 30, 2017

(54) "Interleaved Transformer and Method of Making the Same"

(71) Applicant: GLOBALFOUNDRIES Inc., Grand Cayman (KY)

(72) Inventor: Venkata Vanukuru, Bangalore (IN)

(21) Appl. No.: 15/168,798

(22) Filed: May 31, 2016

(51) Int. Cl. H01F 27/34; H01F 41/04; H01F 27/28; H01L 49/02; H01L 21/3205

(52) U.S. Cl. CPC H01F 27/346; H01L 28/10; H01L 21/32051; H01F 27/2804; H01F 41/041; H01F 2027/2809

(57) ABSTRACT

A high performance, on-chip transformer having interleaving primary and secondary windings to achieve higher coupling coefficient while providing desired impedance transformation is disclosed. The primary winding is formed of two or more parallel conductive winding paths or segments. The secondary winding is embedded within the parallel paths of the primary windings. The transformer primary and secondary spiral turns are joined together using underpass/overpass connections made by breaking open a portion of secondary and primary spiral. Also electrically conductive cross-over junctions are used to establish equal path length across the spiral turns of the primary winding to minimize the magnetic losses and thus the spiral resistance at RF. Further, vias and cross-over junctions are also used to series stack the windings of secondary in an in-out and up-down fashion to enhance secondary inductance and thus impedance transformation.

### BACKGROUND OF THE INVENTION

### 1. Field of the Invention

The field of the invention relates to a high performance, on-chip transformer typically utilized in RF circuits. In particular, it relates to the improved on-chip transformers and methods of making the same. Specifically, the transformer presents interleaving primary and secondary windings to establish impedance transformation, differential-to-single conversion (and vice versa), DC isolation, and bandwidth enhancement.

### 2. Description of Related Art

On-chip transformers are key passive components in radio frequency/millimeter wave integrated circuits. In the design of semiconductor device radio frequency integrated circuits, inductors and transformers are very important devices to be considered. It has been shown that along with the miniaturization of devices, the traditional planar type of transformer, which occupies a large area, fails to conform to current demands.

An integrated transformer is typically used at the output of an RF circuit, where it is used for signal balancing in the conversion of a differential signal coming out of power amplifiers into a single-ended signal to be applied to the antenna. Transformers can also be used to convert a first single-ended signal into a second single-ended signal, of the same or a different voltage depending on the number of turns of the coils.

An on-chip transformer is a critical component for RF microelectronic devices. It is required in RF circuits for impedance transformation, differential-to-signal conversion, such as converting an unbalanced signal to a balanced one, or vice versa (Balun Transformer), isolation, or bandwidth enhancement. Enhancing a transformer on a semiconductor device is essential to device improvement and operation.

Critical parameters that establish high performance transformer operation in an RF application include the enhancement of the coefficient of coupling K, the footprint or area occupied by the device on a substrate, the impedance transformation factor, and the power gain, insertion loss, and efficiency.

Silicon on Insulator wafer technology is made more costly by the utilization of a larger footprint transformer. A larger footprint correlates to increased product cost. If further requires effective use of BEOL metallization to reduce the transformer area. Consequently, there is a need in the art for an integrated circuit transformer that provides for a smaller footprint (higher density) with better coupling and efficiency capabilities. Other integrated circuit transformers lack these design features.

In U.S. Patent Publication No. 2008/0272875 of Huang, et al., titled “Interleaved Three-Dimensional On-Chip Differential Inductors and Transformers,” multiple layered transformer devices are fabricated using mainstream standard processes. Huang separates each turn of a coil into two partial windings and places them interleaved in different layers. In this manner, interleaved 3D on-chip differential transformers are provided with decreased parasitic capacitances, higher coupling efficiency, and higher Q factor. In Huang, “interleaved” refers to a configuration of at least two coils sharing a common axis (for example, in the vertical direction), and running generally parallel to each other. However, it is noted that this design provides an undesirable lower Q of the transformer primary and secondary windings.

In U.S. Pat. No. 7,405,642 issued to Hsu, et al., titled “Three Dimensional Transformer,” the primary and secondary windings of a three dimensional transformer is spread across multiple metal layers, where each metal line of the first and second coil are correspondingly arranged to the opposite side of each other. According to the 3-D transformer of Hsu, along an x-y plane, the first and second coil of each layer are correspondingly arranged to the opposite side of each other. Along the Z-direction, the first and second coil are alternately stacked. Therefore, not only the first and second coil can be coupled along the x-y plane, they can be coupled in the z-direction to further improve the coupling rate. In this prior art design, a lower Q and a lower turns ratio results from the design topology.

In U.S. Patent Publication No. 2011/0032065 of Raczkowski, titled “Two Layer Transformer,” a symmetrical transformer with a stacked coil structure is taught; the coils being located in two conductive planes. Although better symmetry is presented by the Raczkowski design, the design also lends itself to a lower turns ratio and inductance density.

It is desirable to design and fabricate on-chip transformers with characteristics of small size, high quality factor (Q factor), large inductance, high coupling efficiency, and high self-resonating frequency that are improved from known devices in the art. It is important to make on-chip transformers consume as little real estate as possible to mitigate large parasitic capacitance between the on-chip transformer and the substrate in order to reduce unwanted noise.

### SUMMARY OF THE INVENTION

Bearing in mind the problems and deficiencies of the prior art, it is therefore an object of the at least one embodiment to provide a high density, high coupling, high efficiency transformer for integrated circuit applications.

It is another object of at least one embodiment to provide a transformer for integrated circuit applications where the secondary coil or winding is embedded at each spiral turn and fabrication layer within a primary coil or winding.

The above and other objects, which will be apparent to those skilled in the art, are achieved in the embodiment(s) of the invention which is directed to a planar transformer for an integrated circuit, the transformer having an embedded coil structure comprising: a primary winding or coil turn including at least two substantially parallel conductive path segments having a distance therebetween; and a secondary winding or coil turn comprising a secondary conductive path segment embedded between the two conductive paths of the primary coil.

The primary winding may comprise a single or multiple layer(s) of parallel stacked conductive path segments. The secondary winding or coil may include turns formed a single or multiple layer(s) of parallel stacked conductive path segments embedded between the conductive path segments of the primary coil.

Adjacent primary winding conductive path segments may be joined using underpass and overpass connections without electrically shorting to the respective secondary coil conductive path segments. In addition, the secondary winding conductive path segments may be joined using underpass and overpass connections without electrically shorting to the respective primary coil conductive path segments.

In one embodiment, at least two primary coil turns are joined using cross-over junctions, the cross-over junctions forming an electrical path from one primary segment to an adjacent primary segment formed by breaking open a portion of the primary coil segments at one or more metal layers of the integrated circuit without shorting to the secondary coil segments. Similarly, at least two secondary coil turns may be joined using cross-over junctions, the cross-over junctions forming an electrical path from one secondary coil segment to an adjacent secondary coil segment formed by breaking open a portion of the secondary coil segments at one or more metal layers of the integrated circuit without shorting to the primary coil.

An outmost segment of the primary turn is electrically connected to an innermost segment of an adjacent primary turn, such that an electrical conductive path length of the outermost segment of the primary turn is approximately equal to an electrical conductive path length of the innermost segment of the primary turn. Additionally, the spiral turns of the secondary conductive paths may be embedded after (i/2) segments of the primary coil, when the primary segments total an even number of segments, or wherein the spiral turns of the secondary conductive paths are embedded after (i/2+1) segments of the primary coil, when the primary segments total an odd number of segments.

In another embodiment, the conductive path segments of the secondary winding are electrically connected across metal layers to form series stacked spirals. The conductive path segments of the secondary winding may be electrically connected in a spiral-in/spiral-out series configuration across metal layers. Or, conversely, the conductive path segments of the secondary winding are electrically connected in a spiral-up and spiral-down series configuration.

The planar transformer may include a low-K inter-layer dielectric to reduce capacitance between the series stacked spiral turns across metal layers. The lower spirals of the secondary winding are vertically offset from upper spirals in order to reduce inter-layer capacitance, or to reduce inter-layer capacitance.

In a second aspect, a transformer for an integrated circuit is presented, the transformer having an embedded coil structure comprising: a primary winding or coil turn including at least two substantially parallel conductive path segments having a distance therebetween, wherein each of the at least two substantially parallel conductive path segments comprise stacked conductive path segments arranged in a top metal layer and a bottom metal layer; and a secondary winding or coil turn comprising a secondary conductive path segment embedded between the two conductive paths of the primary coil, wherein the secondary conductive path segment comprises stacked conductive path segments arranged in the top metal layer and the bottom metal layer.

The transformer may include magnetic material formed across layers to increase inductance density of the secondary winding. The primary and secondary windings include changing width and spacing across spiral turns, wherein the changing width and spacing may be formed across various metal layers.

A secondary to primary spiral turns ration can be made greater than 1:1 by changing the number of secondary spirals at each metal layer.

The transformer may include high-μ magnetic material across the spiral turns to increase inductance density. The transformer may also include crisscross electrical connections across the spiral turns of both primary and secondary windings.

In a third aspect, a method of making a transformer for an integrated circuit is presented, comprising forming a first metallization layer on a semiconductor substrate, the first metallization layer including at least a first primary winding or coil segment comprising two parallel conductive paths with a distance therebetween, and at least a corresponding first secondary winding or coil segment embedded between the two parallel conductive paths of the first primary coil segment.

The method includes forming a second metallization layer on the semiconductor substrate including at least a second primary winding or coil segment having two parallel conductive paths with a distance therebetween, and at least a second corresponding secondary winding or coil segment embedded between the two parallel conductive paths of at least the secondary primary coil segment; forming an electrically conductive overpass/underpass cross-over junction at the intersection of the first primary coil segment and the second primary coil segment; and forming an electrically conductive overpass/underpass cross-over junction at the intersection of the first secondary coil segment and the second secondary coil segment.

The first primary coil segments of the primary coil and the first secondary segments of the secondary coil may be of constant width.

The primary segments may be designed wider than the embedded secondary segments to reduce series losses and increase current handling.

Some secondary segments may be formed to be electrically connected in an up-down manner from the first metallization layer to the second metallization layer while simultaneously embedded within each parallel conductive path of the primary coil.

### BRIEF DESCRIPTION OF THE DRAWINGS

The features of the invention believed to be novel and the elements characteristic of the invention are set forth with particularity in the appended claims. The figures are for illustration purposes only and are not drawn to scale. The invention itself, however, both as to organization and method of operation, may best be understood by reference to the detailed description which follows taken in conjunction with the accompanying drawings in which:

FIGS. 1A and 1B depict a comparison of a stacked prior art transformer design 100 (FIG. 1A) to the stacked transformer of one embodiment of the invention (FIG. 1B);

FIG. 2A depicts a cross-sectional layout of the fabrication layers of a two-layer parallel stacked interleaved transformer;

FIG. 2B depicts a cross-sectional layout of the fabrication layers of a three-layer parallel stacked interleaved transformer;

FIG. 3 depicts a cross-sectional layout of the fabrication layers of a layered parallel stacked interleaved transformer having varying spiral thickness across the primary and secondary turns;

FIG. 4 depicts an interleaved transformer with varying primary and secondary spiral width and spacing across metal layers;

FIG. 5 depicts an interleaved transformer with varying primary and secondary spiral width and spacing across a number of turns;

FIGS. 6A and 6B depicts an embodiment of an interleaved transformer with varying primary and secondary spiral turns ratio. In FIG. 6A, two spiral secondary turns (S1, S2) are embedded between the first and second primary segments for each cross-sectional set. An additional secondary turn is embedded between two primary turn segments as depicted in FIG. 6B;

FIG. 7 depicts simulation results of the coupling coefficient as a function of frequency for the transformer design depicted in FIG. 1B;

FIG. 8 represents a comparison of “maximum available gain” of a prior art design to the design of the transformer depicted in FIG. 1B;

FIG. 9 depicts an embodiment of the planar transformer having a primary winding with an equal path length;

FIG. 10 depicts the cross-section of a two layer parallel stacked interleaved transformer with two-segment equal path length architecture;

FIG. 11 depicts a two layer parallel stacked interleaved transformer with a three segment equal path length architecture;

FIG. 12 depicts a two layer parallel stacked interleaved transformer with a four segment equal path length architecture;

FIG. 13 depicts the spiral-up/spiral-down embodiment of a series stacked secondary winding;

FIG. 14A depicts a cross-sectional view of a two-layer interleaved transformer with a parallel stacked primary winding and a spiral in and spiral out series stacked secondary winding;

FIG. 14B depicts a three layer interleaved transformer with parallel stacked primary windings and spiral in/spiral out series stacked secondary windings;

FIGS. 15A and 15B depict another embodiment of a spiral configuration for the secondary winding. In FIG. 15A, a two layer interleaved transformer with a parallel stacked primary winding and a spiral-down/spiral-up series stacked secondary winding is shown. FIG. 15B depicts a three layer interleaved transformer with parallel stacked primary and spiral-down/spiral-up series stacked secondary winding;

FIGS. 16A and 16B depict configurations of equal path lengths of the windings for both the primary and secondary turns. In FIG. 16A, a two layer interleaved transformer with parallel stacked primary and spiral-down/spiral-up series stacked secondary is shown.

In FIG. 16B, the current is cross-linked for each turn, whereby, for the first turn, current is directed from one layer to the next in a crossing pattern;

FIG. 17 depicts a two layer interleaved transformer with parallel stacked primary windings and spiral-in/spiral-out series stacked secondary windings with offset of the secondary between turns;

FIG. 18A depicts a three layer interleaved transformer with parallel stacked primary windings and spiral-in/spiral-out series stacked secondary windings that skip the M4 (middle) metal layer; and

FIG. 18B depicts a three layer interleaved transformer with parallel stacked primary windings and spiral-out/spiral-in (i.e., spiral-down/spiral-up) series stacked secondary windings that skip the M4 (middle) metal layer.

### DESCRIPTION OF THE PREFERRED EMBODIMENT(S)

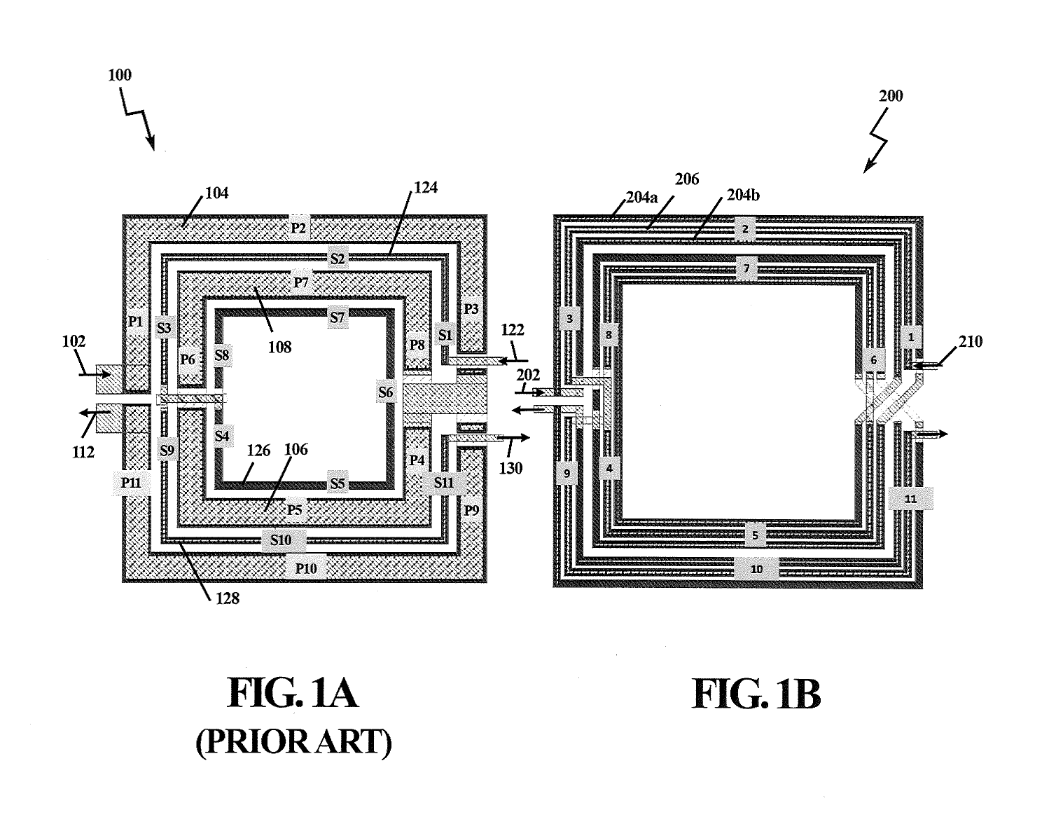

In describing the embodiment(s), reference will be made herein to FIGS. 1-18 of the drawings in which like numerals refer to like features of the invention.

In at least one embodiment an interleaved transformer is depicted which uses multiple metal layers to achieve target inductance. For multiple turns at a given level, the complexity of this structure requires design solutions beyond the current state of the art. The implementation of prior art applications would necessarily require a high number of vias for layer-to-layer operation, which increases the transformer's DC resistance. The design discloses a transformer structure that utilizes a primary spiral divided into segments, and a secondary spiral that is embedded within the primary spiral segment for an increased coupling coefficient, using a reduced number of vias.

FIGS. 1A and 1B depict a comparison of a stacked prior art transformer design 100 (FIG. 1A) to the stacked transformer of one embodiment of the invention 200 (FIG. 1B). As shown, the width of the windings of the prior art design changes, which in turn changes the inductance and impedance of the design. Referring to FIG. 1A, and following the spiral current path of the primary winding or coil, beginning with the input current port 102, the current traverses through first segment 104 as identified by segment portions P1, P2, P3. This is a wide primary path as compared to the width of the secondary path. The primary path of first segment 102 then changes width as segment portion P3 is electrically connected to segment portions P4, P5 of the second, internal primary segment 106. Second internal primary segment 106 is electrically connected to third primary segment 108, identified by segment portions P6, P7, P8. Segment portion P8 of third segment 108 is electrically connected to outer segment 110, represented by segment portions P9, P10, P11, which ultimately lead to output current port 112. In this configuration, the primary path is a relatively wide conductor path, spiraled with an inner winding and an outer winding. The changes in width cause unwanted inductance changes and impedance changes in the primary winding.

Similarly, in the prior art design of FIG. 1A, the secondary winding spirals in a similar fashion, internal to the outermost winding of the primary path. Secondary winding input 122 allows for current to travel through a first secondary winding segment 124, represented by segment portions S1, S2, S3. Secondary segment portion S3 is electrically connected to a second internal secondary winding segment 126, represented by secondary segment portions S4-S8. Secondary segment portion S8 is then electrically connected to third secondary winding segment 128, which is external to segment 126. The current traversing secondary segment 128 follows secondary segment portions S9, S10, S11 and exits at the secondary winding output 130. Again, it is noted that width variations in these windings instigate unwanted inductance and impedance changes.

FIG. 1B depicts a top view of the layout of an embodiment of interleaved transformer 200. Parallel stacking is performed by this design, insomuch as each layer is designed to carry the same current in the same direction. Following the path of the spiral stacked, primary winding, beginning at primary input 202, the wide primary winding of the prior art is separated into two distinct paths, an outer path 204a and an inner path 204b. The outer and inner paths 204a,b encompass the secondary winding current path 206; that is, the secondary winding is interleaved within the primary winding. Each conductor segment is approximately the same width as the next segment, which promotes consistent inductance and impedance transformation. The path of the secondary winding input 210 is depicted by numbered segmented portions 1-11, where each segmented portion enjoys the same width as the next. Overpass/underpass cross-over connections occur at segmented portions 3 to 4, and 8-9. Furthermore, the cross-over connections attach segmented portions 3 to 4 and 8 to 9 at different layers of the substrate. These segments carry the same current in the same direction, and are configured for parallel stacking.

Notably in this embodiment, secondary spiral segmented portions are embedded within primary spiral segmented portions. Both the primary and secondary coils comprise an arbitrary number of parallel stacked spiral segments. In certain instances, in the case of parallel stacking, when one of the spiral segments is broken, an overpass/underpass connection is provided to complete the primary or secondary winding.

Several modifications may be made to the windings to enhance performance. For example, in one embodiment, it is possible to reduce the number of primary spiral turns by making them wider. This reduces the series loss while simultaneously increasing the current handling. In another embodiment, the top section of the secondary spiral segments or turns may also be designed with gradually decreasing width and increasing spacing from the outermost turn to the innermost turn to mitigate series losses.

Additionally, the bottom section of the secondary spiral turns may use the advantage of finer spacing to increase the overall turns-ratio. This bottom section may also have wider track widths than the top section to reduce series losses and increase current handling. Furthermore, the bottom section of the secondary spiral turns may be offset from the primary turns to increase the high frequency performance at the cost of a slightly reduced turns-ratio.

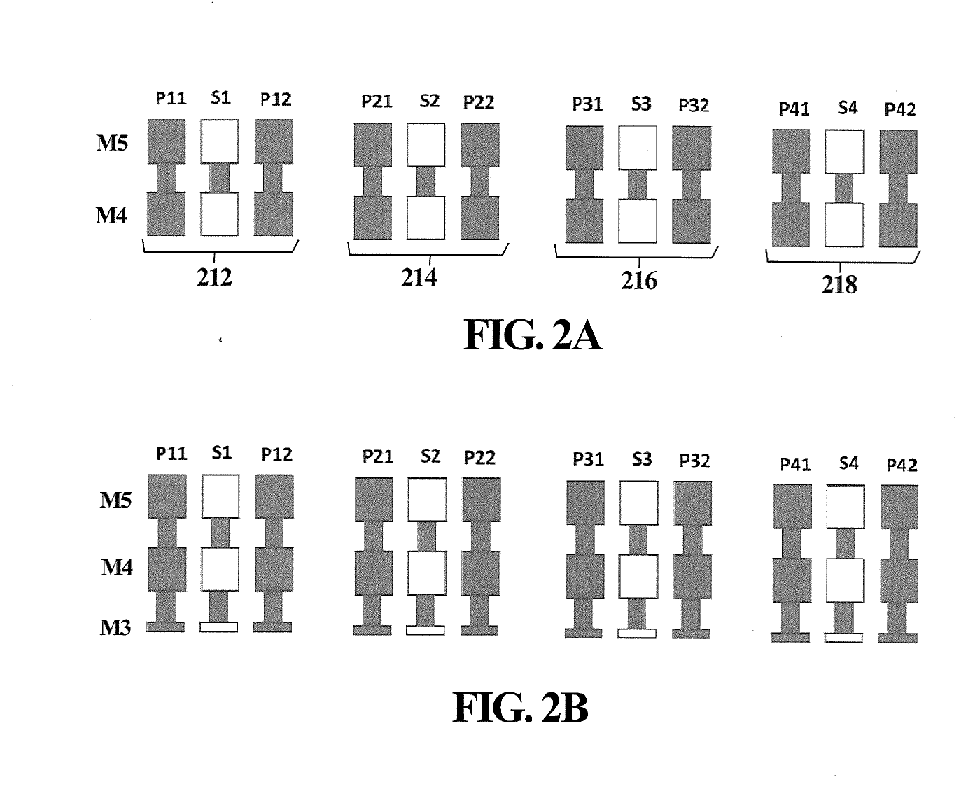

FIG. 2A depicts a cross-sectional layout of the fabrication layers of a two-layer parallel stacked interleaved transformer. There are four winding cross-section sets depicted 212, 214, 216, and 218. Each cross-section set includes a first primary turn having two segments, and a secondary turn embedded between the two primary segments of the first primary turn. Each primary element of the cross-sectional set is represented symbolically as follows:

P_{i,j}
where,
   i represents the i^{th} turn; and
   j represents the j^{th} segment.

Thus, the first primary turn of cross-sectional set 212 has two primary segments (P_{1,1} and P_{1,2}). Embedded between the P₁₁ and P₁₂ segments is the secondary turn represented symbolically as: S₁, where “i” represents the i^{th} turn, which coincides with the i^{th} turn of the primary windings.

As noted, there are two metal layers M4 and M5 that assist in forming the windings for each turn. The primary winding is split into bi-level first primary segments P₁₁ and P₁₂. Each segment includes a conductive component or bar via on both the M4 and M5 layers. The bar via runs throughout the length of the spiral winding. The bi-level secondary S₁ is sandwiched between P₁₁ and P₁₂, and also includes a conductive component (bar via) between the M4 and M5 layers. Each additional cross-sectional set includes a pair of primary segments and a respective secondary segment. For example, the second cross-sectional set 214 includes the following arrangement of primary turns with a secondary segment embedded therebetween: P₂₁, S₂, P₂₂; the third cross-sectional set 216 includes P₃₁, S₃, P₃₂; and the fourth cross-sectional set 218 includes P₄₁, S₄, P₄₂. Although four cross-sectional sets are depicted, the invention is not so limited, and the n^{th} turn may be depicted as Pₙ₁, Sₙ, P_{n,2}.

FIG. 2B depicts a cross-sectional layout of the fabrication layers of a three-layer parallel stacked interleaved transformer. There are three metal layers as shown, M3, M4 and M5. The bottom or lower layer, M3, is designed to be thinner than the upper layers to facilitate FEOL manufacturing. In a similar fashion to the two-layer parallel stacked layout, there are two primary segments for each turn (P_{i,1} and P_{i,2}), each primary turn having a secondary turn, S₁, embedded between the two primary segments. In this embodiment, the primary is split into tri-level conductors. Each segment includes a conductive component (bar via) between the M3 and M4 layers, and between the M4 and M5 layers. The secondary S₁, sandwiched between P₁₁ and P₁₂, also includes a conductive component (bar via) between each of the M3-M5 layers. As noted with the two-layer parallel stacked interleaved transformer, four cross-sectional sets are depicted for the three layer parallel stacked interleaved transformer; however, the invention is not so limited, and the n^{th} turn may be depicted as Pₙ₁, Sₙ, P_{n,2}.

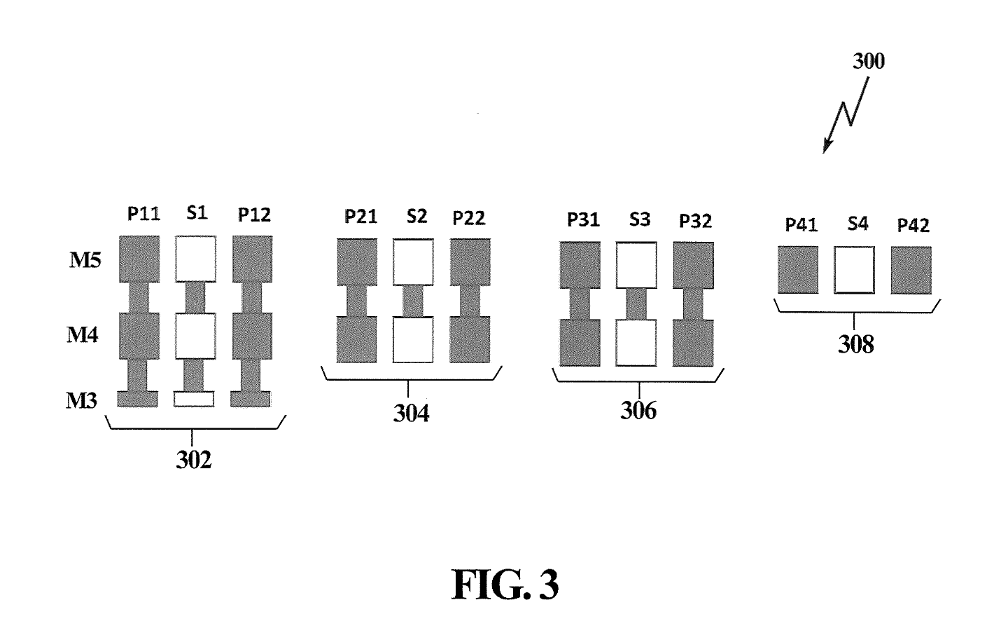

FIG. 3 depicts a cross-sectional layout of the fabrication layers of a layered parallel stacked interleaved transformer having varying spiral thickness across the primary and secondary turns. This embodiment is represented by cross-sectional sets 302, 304, 306, and 308. Cross-sectional set 302 represents the outermost turn, which has an additional metal layer (M3). As the outermost turn, the conductive paths have the longest run, and therefore, the most resistance. Consequently, it is beneficial for the outermost turn to also have the most metal (as compared to the inner turns 304, 306, and 308). As the thickness is increased, the electrical losses decrease. Since the internal turns have less overall conductive length, there is no need for the extra thickness (added metal) to bring down the resistance. Cross-sectional sets 304 and 306 are depicted as two-layer turns, utilizing metal layers M4 and M5. The innermost turn is represented by cross-sectional set 308, which has only one layer. In this manner, the embodiment lends itself to optimization since thickness can be gradually decreased as the winding progresses from the outermost turn to the innermost turn. In all cross-sectional sets, the secondary turn is embedded between two primary segments.

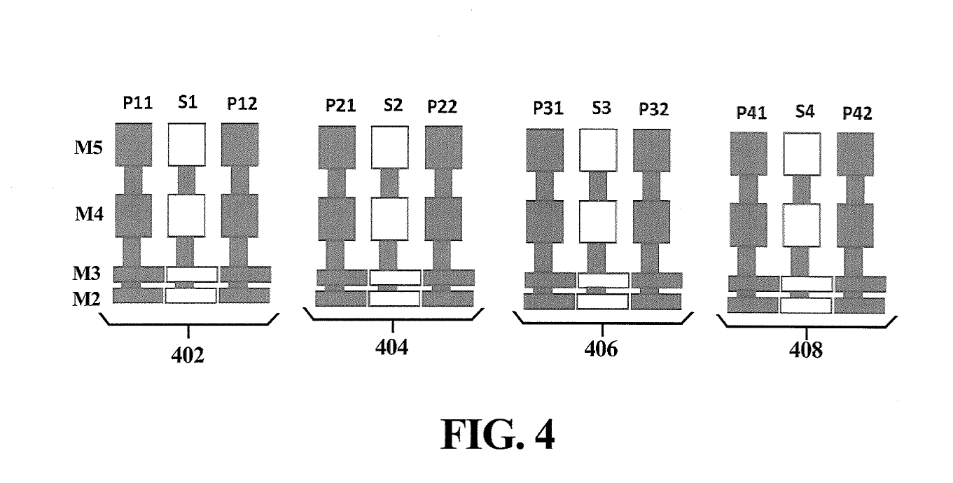

FIG. 4 depicts an interleaved transformer with varying primary and secondary spiral width and spacing across metal layers. In this embodiment, depicting cross-sectional sets 402, 404, 406, and 408, the lower primary and secondary turns are composed of two separate metal layers (M2 and M3), each connected by a bar. These metal conductor layers are thinner than the upper two layers, and also wider. As the thickness of the conductors is decreased for the lower two metal layers (M2 and M3), the width of these conductors is increased in order to decrease the resistance in the turn. There is also minimum spacing between the M2 and M3 layers, as opposed to greater spacing between M4 and M3, and between M4 and M5.

It is further envisioned that an interleaved transformer with varying spiral thickness across the primary and secondary turns, as is taught in FIG. 3, may be combined with the varying primary and secondary width of the lower metal layers, especially for the outermost turn.

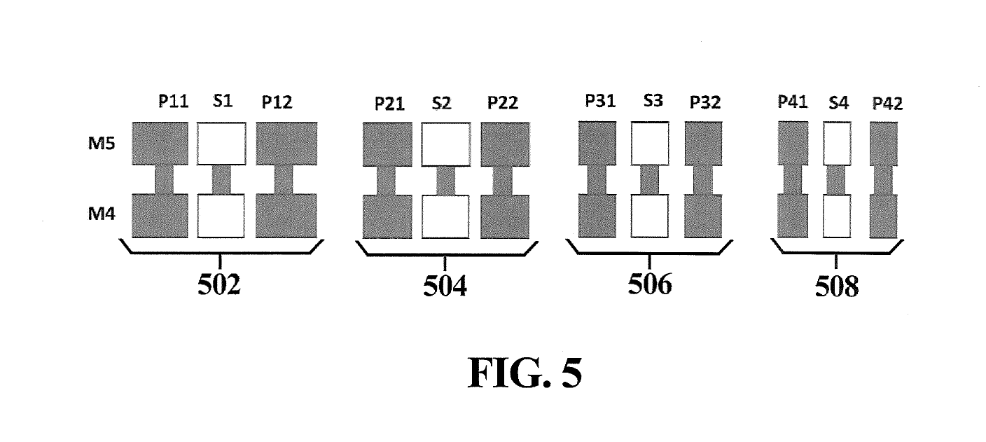

FIG. 5 depicts an interleaved transformer with varying primary and secondary spiral width and spacing across a number of turns. Cross-sectional sets 502, 504,506, and 508 have different widths for their respective conductive paths, starting with the widest cross-section for the outermost turn (cross-sectional set 502) to the narrowest cross-section for the innermost turn (cross-sectional set 508). The change in widths is a compensation for different path lengths as each turn proceeds from the outside to the inside. Essentially, in this embodiment, electric and magnetic losses are addressed through width variation.

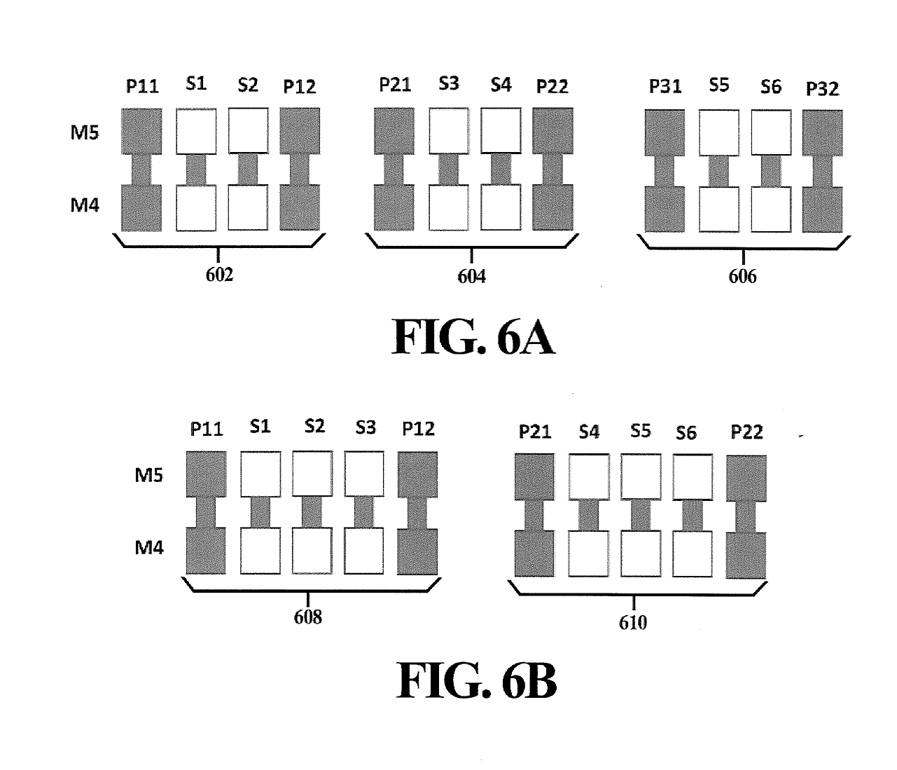

FIGS. 6A and 6B depicts an embodiment of an interleaved transformer with varying primary and secondary spiral turns ratio. In the embodiment shown in FIG. 6A, there are two spiral secondary turns (S₁, S₂) embedded between the first and second primary segments (P₁₁, P₁₂) for each cross-sectional set 602, 604, and 606. This increase in the ratio of secondary to primary turns increases the inductance of the secondary to primary (S_{L}, P_{L}), and represents a turns ratio of 1:2.

For illustrative purposes, an additional secondary turn was embedded between two primary turn segments as depicted in FIG. 6B. In this embodiment, three secondary turns (S₁, S₂, and S₃) are formed between the primary segments (P₁₁ and P₁₂) for cross-sectional set 608, and secondary turns S₄, S₅, and S₆ were embedded between primary segments P₂₁ and P₂₂, and represents a turns ratio 1:3.

In the embodiments described above, a planar transformer structure is realized using a primary winding with spiral turns, wherein each spiral turn may include one or more parallel stacked metal layers with each spiral turn split into multiple segments. Furthermore, the secondary winding includes respective spiral turns as well using one or more parallel stacked metal layers, such that the respective secondary spiral turns are embedded laterally within the segments of the primary spiral turns.

As will be discussed further herein, in one embodiment these multiple segments are interconnected in such a way that their path lengths are equal. For example the outermost segment of a given spiral turn is connected to the innermost segment of the subsequent spiral turn.

In another embodiment, spiral turns of the secondary winding are embedded after (i/2) segments of the primary, when the number of primary segments (i) are even. In yet another embodiment, the spiral turns of the secondary winding are embedded after (i/2+1) segments of the primary, when the number of primary segments are odd.

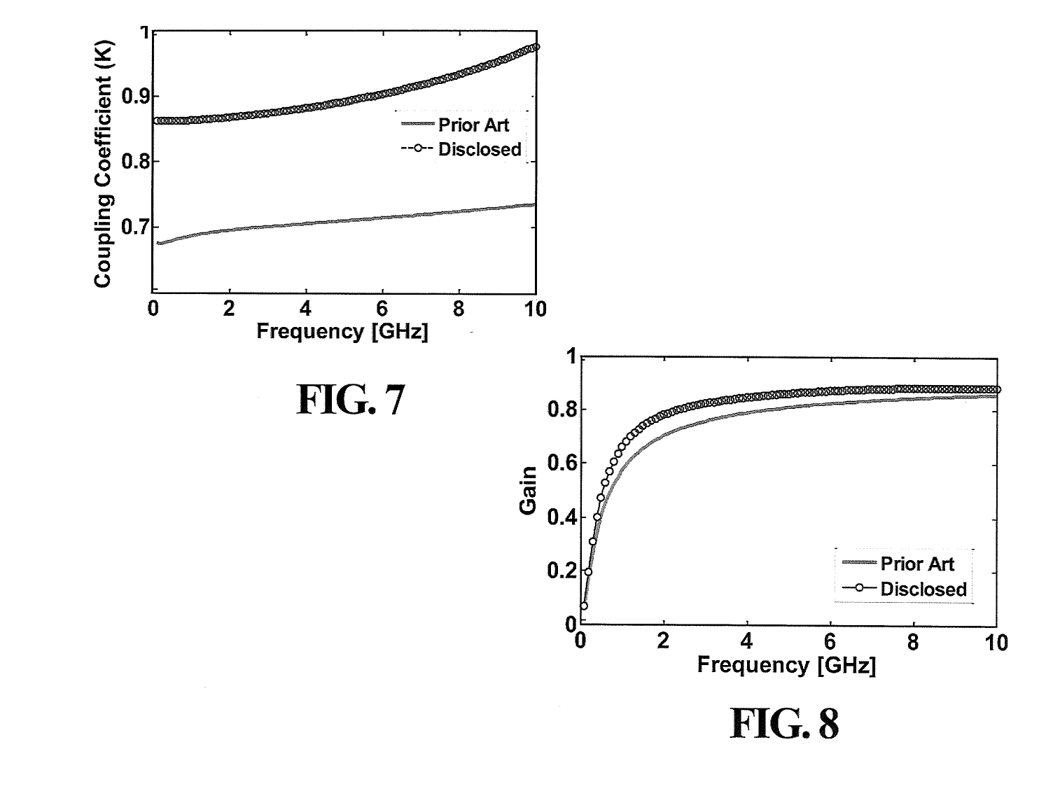

FIG. 7 depicts simulation results of the coupling coefficient as a function of frequency for the transformer design depicted in FIG. 1B. The coupling coefficient is a value from zero to one that represents a ratio of the mutual inductance of the transformer to the primary and secondary inductances. For coupling, the primary and secondary windings are measured separately, and applied to the following equation:

$$k = \frac{M}{\sqrt{{L}_{p} {L}_{s}}}$$

where,
   k is the coefficient of coupling, zero to one; and
   M is the mutual inductance.

The mutual inductance, M, is empirically determined by measuring the inductance of the primary and secondary in series, and then interchanging the connections of one of the windings for a second reading, and using these values in the following expression:

$$M = \frac{1}{4} ( {L}_{series +} - {L}_{series -} )$$

FIG. 8 represents a comparison of the coupling coefficient of a prior art design to the design of a first embodiment. As noted, the coupling coefficient is significantly higher than that of the prior art, and increases with increasing frequency. Quantitatively, the coupling coefficient is shown to be on the order of twenty-five percent (25%) greater than that of the prior art. For this simulation, the width of the primary was established as 16 μm, the width of the secondary was established as 4 μm, the outer diameter 200 μm, and the number of turns for the primary and secondary windings was held at two (2).

Using the same simulation parameters, FIG. 8 compares the gain of a prior art design to the design of the first embodiment. As noted, the gain is higher than that of the prior art across the frequency spectrum. Quantitatively, the gain is shown to be on the order of ten percent (10%) greater than that of the prior art.

Another advantage is the promotion of equal path length for the primary winding. Due to the interleaving nature of the design, the planar transformer establishes an equal path length for the primary. This is possible because the primary winding is effectively shared across two current paths, where the outermost segment of one path of the primary winding is electrically connected to the innermost segment of the adjacent primary winding segment.

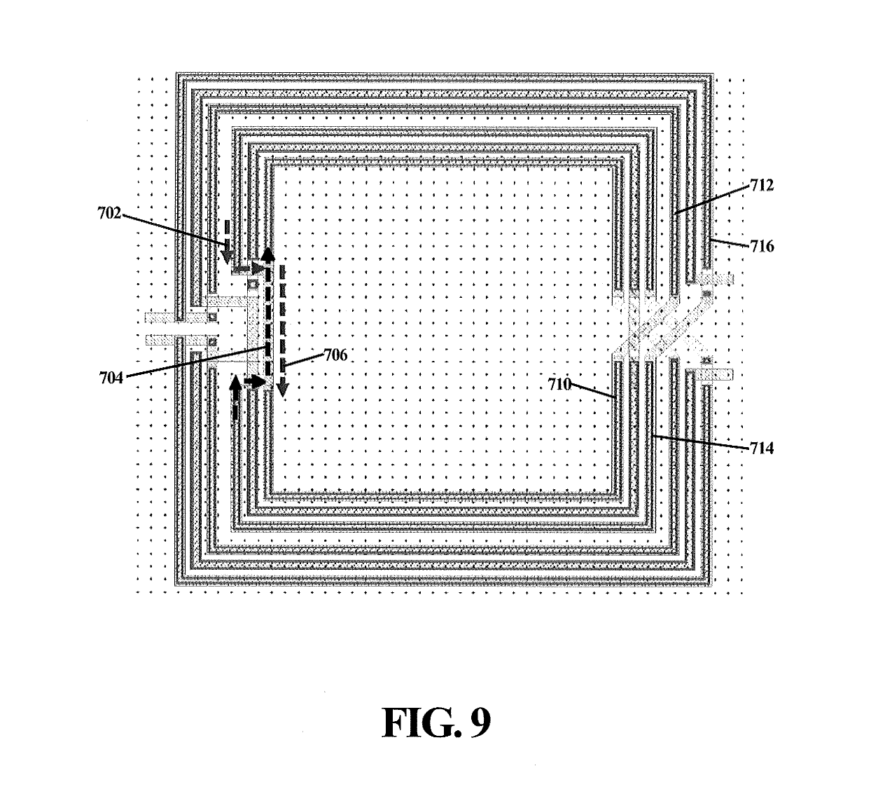

FIG. 9 depicts an embodiment of the planar transformer having a primary winding with an equal path length. The inner primary winding segment 702 is shown connected to the adjacent inner primary winding segment 704 in a manner that ensures equal path length for current within the primary winding. Following current path 706, current in inner primary winding segment 710 is placed in electrical communication with inner primary winding segment 712 of the adjacent outer turn, and current in inner primary winding segment 714 is placed in electrical communication with outer primary winding segment 716 of the adjacent outer turn. This cross-over of these otherwise parallel paths allows for the same electrical path length to be realized by current traversing the primary winding.

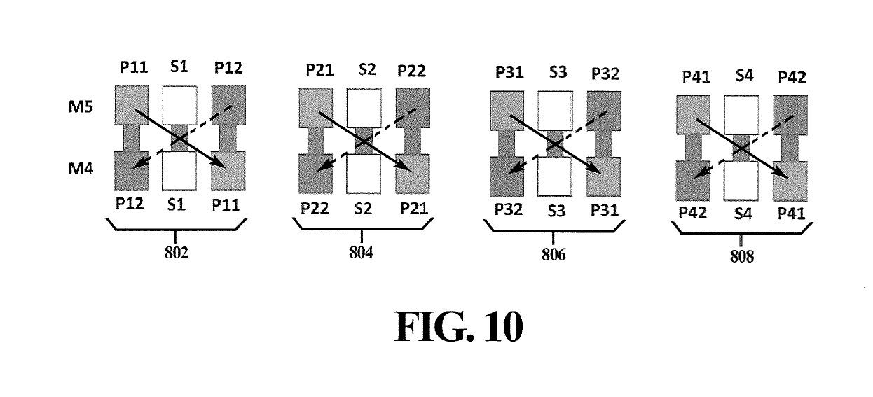

FIG. 10 depicts the cross-section of a two layer parallel stacked interleaved transformer with two-segment equal path length architecture. In this configuration, in cross-sectional segment 802, P₁₁ at M5 connects to P₁₂ at M4; and P₁₂ at M5 connects with P₁₁ at M4. The other cross-sectional segments follow in a similar cross connecting pattern. In cross-sectional segment 804, P₂₁ at M5 connects to P₂₂ at M4; and P₂₂ at M5 connects with P₂₁ at M4. In cross-sectional segment 806, P₃₁ at M5 connects to P₃₂ at M4; and P₄₂ at M5 connects with P₄₁ at M4. Finally, in cross-sectional segment 808, P₄₁ at M5 connects to P₃₂ at M4; and P₄₂ at M5 connects with P₄₁ at M4.

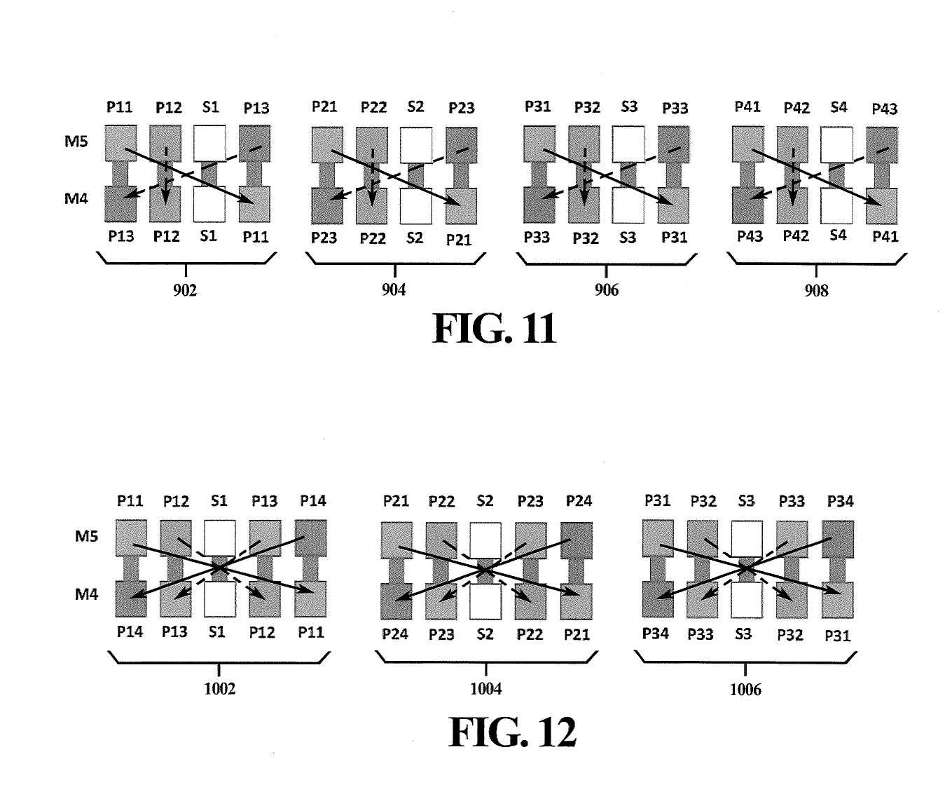

FIG. 11 depicts a two layer parallel stacked interleaved transformer with a three segment equal path length architecture. Four cross-sectional segments are shown, 902, 904, 906, and 908. In this embodiment, using cross-sectional segment 902 as an example, primary segment P₁₁ at M5 is electrically connected to P₁₃ at M4; segment P₁₂ at M5 is electrically connected to P₁₂ at M4; and segment P₁₃ at M5 is electrically connected to P₁₁ at M4. This configuration determines the lowest possible resistance for each turn while maintaining equal path length. This represents a spiral-in/spiral-out configuration. For example, in an eight turn secondary spiral, turns 1, 2, 3, and 4 are on the topmost metal layer, and turns 5, 6, 7, and 8 are on the lower metal layer.

As another example of equal path length, FIG. 12 depicts a two layer parallel stacked interleaved transformer with a four segment equal path length architecture. Cross-sectional segments 1002, 1004, and 1006 are depicted. Using cross-sectional segment 1002 as an example, primary segment P₁₁ at M5 is electrically connected to P₁₄ at M4; segment P₁₂ at M5 is electrically connected to P₁₃ at M4; segment P₁₃ at M5 is electrically connected to P₁₂ at M4; and segment P₁₄ at M5 is electrically connected to P₁₁ at M4. This represents a spiral-up and spiral-down configuration. For example, in an eight turn secondary spiral, turns 1, 3, 5, and 7 are on the topmost metal layer, and turns 2, 4, 6, and 8 are on the lower metal layer.

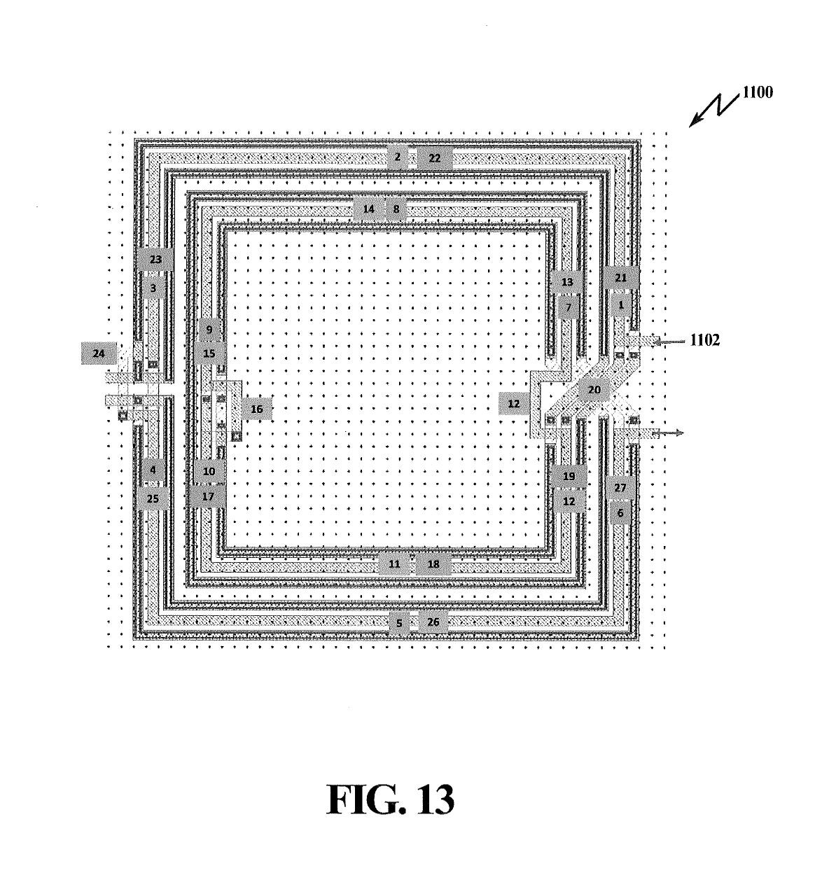

FIG. 13 depicts the up-down embodiment 1100 of a series stacked secondary winding. In this embodiment a secondary winding spiral segment is wound (electrically connected) in an up and down manner while simultaneously embedded in the corresponding (adjacent) primary winding spiral segment. The secondary winding is designed to have a higher inductance than the primary winding. The series-stacking significantly increases the impedance transformation through the use of additional metallization features.

In FIG. 13, the secondary winding's current path is identified by location numbers, and the current direction may be followed by following the consecutive numbering scheme. Starting at the secondary input 1102 the first winding segment represented by location numbers 1-3 is located on the top metal layer. At the overpass or underpass cross-over point between locations 3 and 4, the secondary segment shifts from the top metal layer to a lower metal layer, and traverses the lower metal layer through locations 4-6. At this cross-over junction (between locations 6 and 7), the secondary winding segment remains on the lower metal layer through locations 7-9, and shifting again to the top metal layer at the cross-over junction situated between locations 9 and 10. Secondary winding segment represented by locations 10-16 are all located on the top metal layer (even through the cross-over junction located between location numbers 12 and 13). The cross-over junction at locations 16 and 17 shift the secondary segment from the top metal layer to the lower metal layer through locations 17-24 (including at the cross-over junction located at 19 and 21). This topology demonstrates how the secondary winding is stacked in an up-down series fashion. The result is a higher inductance in the secondary than the primary winding due to the increase in metal for the winding. This also results in a higher inductance in the secondary winding over the primary winding. The tracing of the path markers indicates the up-down path of the secondary winding of the transformer.

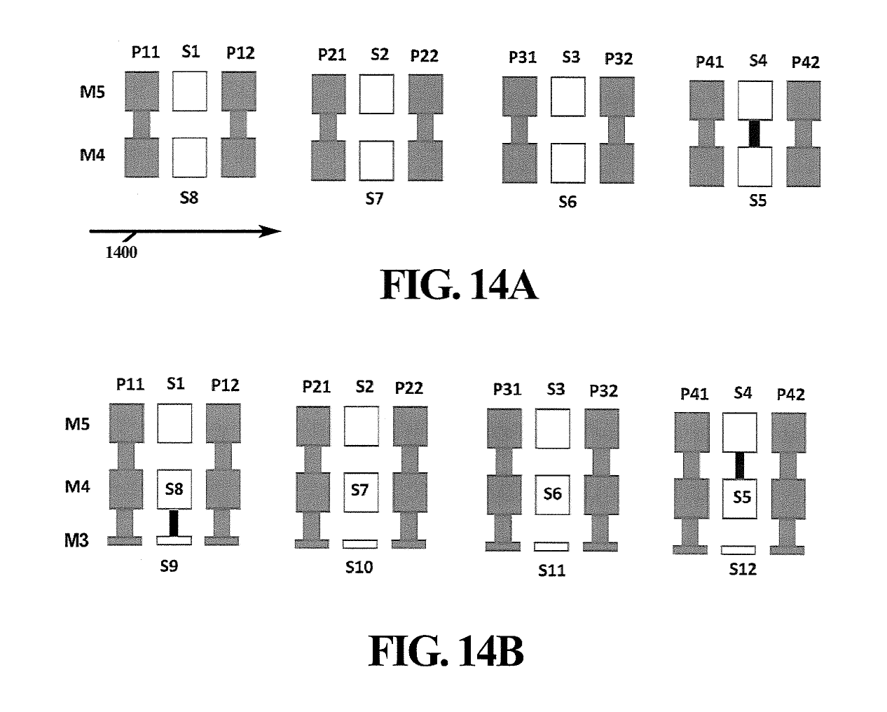

FIG. 14A depicts a cross-sectional view of a two-layer interleaved transformer with a parallel stacked primary winding and a spiral in/spiral out series stacked secondary winding. In this illustrative cross-sectional example, S₁ would have the current running in a direction into the page, while S₈ has current running in a direction out of the page. Thus, the current flow of the secondary demonstrates a “spiral in” configuration changing into a “spiral out” configuration. At S₄, a bar via or other electrical connection electrically attaches the secondary top layer to the secondary bottom layer at S₅. As noted by arrow 1400, the diameter of each winding turn decreases in the direction of the arrow. Based on this configuration, M4 and M5 are wired in series.

Following on the two-layer embodiment of FIG. 14A, FIG. 14B depicts a three layer interleaved transformer with parallel stacked primary windings and spiral in/spiral out series stacked secondary windings. In this added layer embodiment, S₈ is now in electrical communication with the lowest metal layer M3 at S₉. The lower metal layer is also a thinner layer. This configuration may be extended to any number of layers. Additionally, the outermost primary turns may have variable thickness and width, as previously discussed in prior embodiments.

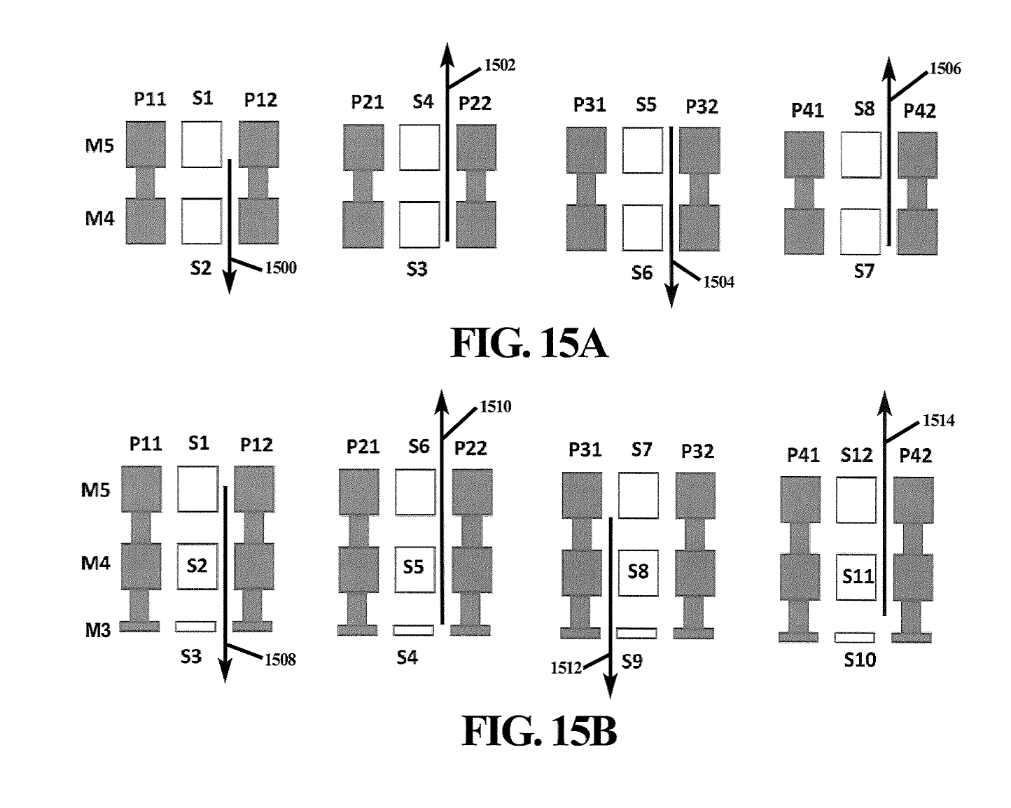

FIGS. 15A and 15B depict another embodiment of a spiral configuration for the secondary winding. In FIG. 15A, a two layer interleaved transformer with a parallel stacked primary winding and a spiral down/spiral up series stacked secondary winding is shown. The secondary winding allows for current to flow from the upper metal layer (M5) to the lower metal layer (M4) and back again, as noted by directional arrows 1500, 1502, 1504, and 1506. This configuration serves to limit or reduce the interlayer capacitance.

Similarly, in a three layer interleaved transformer with parallel stacked primary and spiral-down/spiral up series stacked secondary depicted in FIG. 15B, the current flow is from top metal layer M5 to lower metal layer M3, and back again for each secondary turn as depicted by the directional arrows 1508, 1510, 1512, 1514).

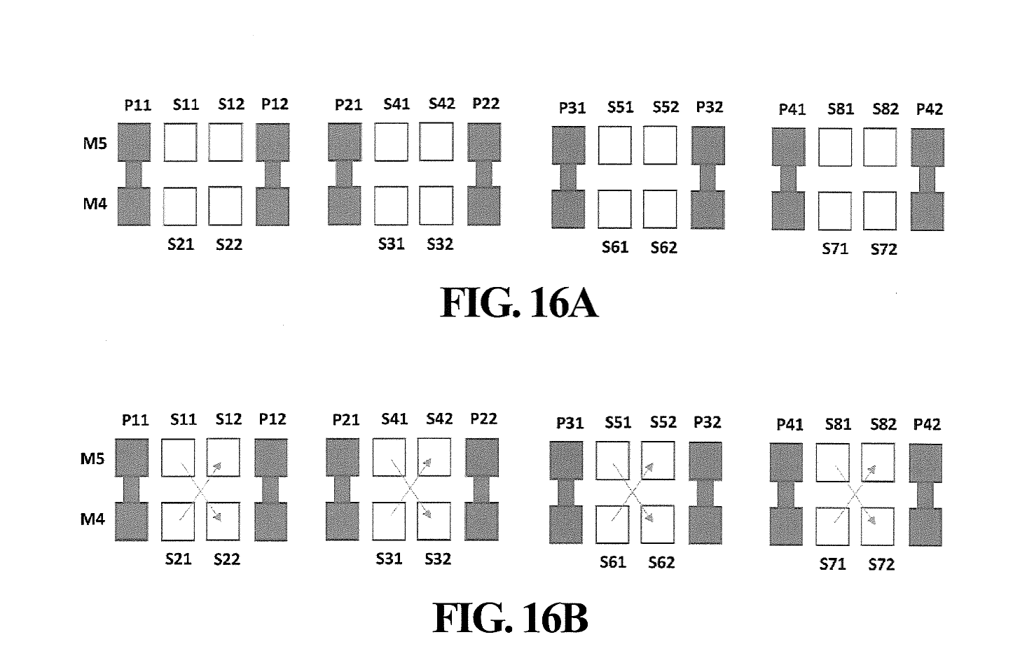

FIGS. 16A and 16B depict configurations of equal path lengths of the windings for both the primary and secondary turns. In FIG. 16A, a two layer interleaved transformer with parallel stacked primary and spiral down/spiral up series stacked secondary is shown. As taught, the embedded secondary winding comprises two separate segments over two layers (for example, S₁₁, S₂₁, S₁₂, S₂₂ for the first secondary turn). As with the configuration of FIG. 15, this configuration provides for equal path length (at the secondary as well as the primary). In FIG. 16B, the current is cross-linked for each turn as depicted by the arrows, whereby, for the first turn, current is directed from one layer to the next in a crossing pattern; from S₁₁ to S₂₂, then from S₂₂ to S₂₁, and finally from S₂₁ to S₁₂.

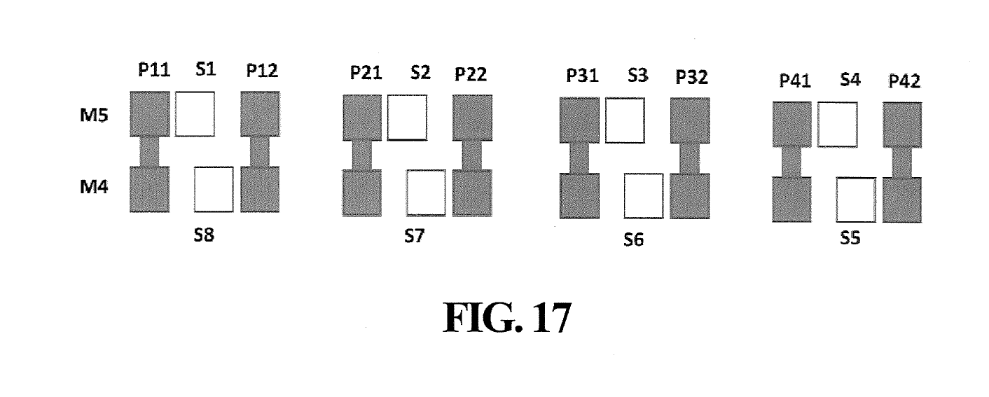

In yet another embodiment, it is possible for the secondary segments of the upper and lower metal layers of each turn to be offset with respect to one another. This offsets adjusts to minimize interlayer capacitance. FIG. 17 depicts a two layer interleaved transformer with parallel stacked primary windings and spiral-in/spiral-out series stacked secondary windings with offset of the secondary between turns.

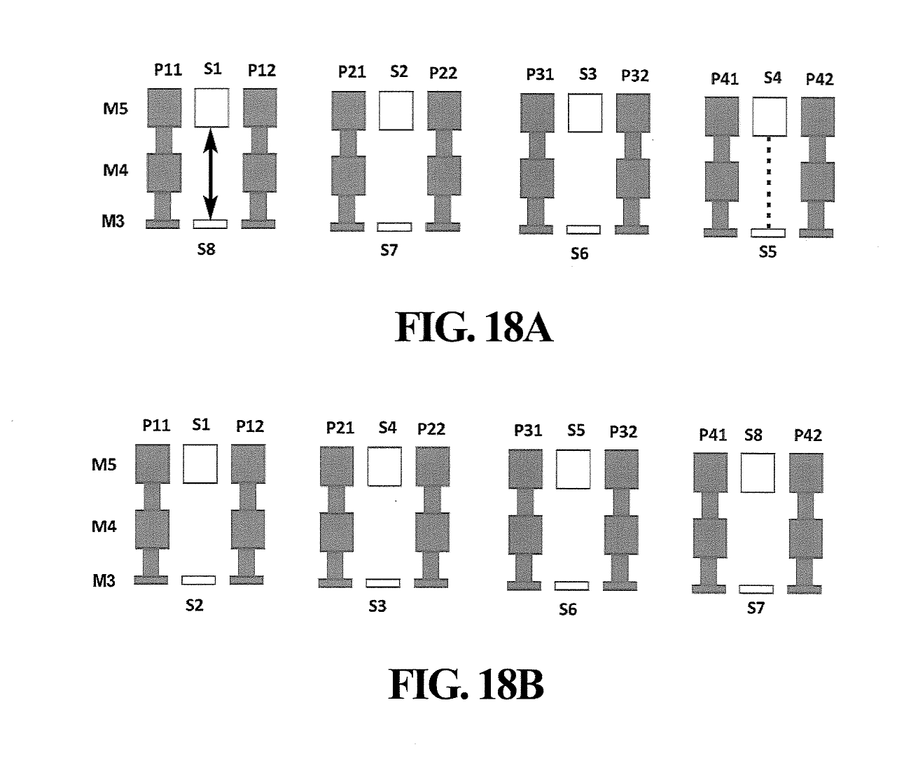

FIG. 18A depicts a three layer interleaved transformer with parallel stacked primary windings and spiral-in/spiral-out series stacked secondary windings that skip the M4 (middle) metal layer. This gap in the secondary turn segments reduces the interlayer capacitance and pushes the higher frequency performance of the device. Similarly, a spiral-out and spiral-in configuration may also be implemented. FIG. 18B depicts a three layer interleaved transformer with parallel stacked primary windings and spiral-out and spiral-in (i.e., spiral-down/spiral-up) series stacked secondary windings that skip the M4 (middle) metal layer.

A method for fabricating the first embodiment described above for a high-Q, interleaved transformer would include the steps of forming two parallel primary path winding segments, preferably equidistant from one another, and forming secondary path winding segments therebetween. Cross-over junctions at each turn segment may electrically connect the outermost primary path of one turn with the innermost primary path of a second turn, which allows for equal current path length over the course of the winding. A method for making the up-down series stacked would include alternating the secondary path winding segments from a lower metallization layer to an upper metallization layer, while maintaining the interleaved configuration of running the secondary winding between two halves of the primary winding.

While the embodiments have been particularly described, in conjunction with a specific preferred embodiment, it is evident that many alternatives, modifications and variations will be apparent to those skilled in the art in light of the foregoing description. It is therefore contemplated that the appended claims will embrace any such alternatives, modifications and variations as falling within the true scope and spirit of the design.

Thus, having described the invention, what is claimed is:

1. A planar transformer for an integrated circuit, said transformer having an embedded coil structure comprising:
a primary winding or coil turn including at least two substantially parallel conductive path segments having a distance therebetween; and
a secondary winding or coil turn comprising a secondary conductive path segment embedded between said two conductive paths of said primary coil.

2. The planar transformer of claim 1 wherein said primary winding comprises a single or multiple layer(s) of parallel stacked conductive path segments.

3. The planar transformer of claim 1 wherein said secondary winding or coil includes turns formed a single or multiple layer(s) of parallel stacked conductive path segments embedded between said conductive path segments of said primary coil.

4. The planar transformer of claim 2 wherein said secondary winding or coil includes turns formed said single or multiple layer(s) of parallel stacked conductive path segments embedded between said conductive path segments of said primary coil.

5. The planar transformer of claim 1 wherein adjacent primary winding conductive path segments are joined using underpass and overpass connections without electrically shorting to the respective secondary coil conductive path segments.

6. The planar transformer of claim 1 wherein said secondary winding conductive path segments are joined using underpass and overpass connections without electrically shorting to the respective primary coil conductive path segments.

7. The planar transformer of claim 4 wherein at least two primary coil turns are joined using cross-over junctions, said cross-over junctions forming an electrical path from one primary segment to an adjacent primary segment formed by breaking open a portion of said primary coil segments at one or more metal layers of said integrated circuit without shorting to said secondary coil segments.

8. The planar transformer of claim 4 wherein at least two secondary coil turns are joined using cross-over junctions, said cross-over junctions forming an electrical path from one secondary coil segment to an adjacent secondary coil segment formed by breaking open a portion of said secondary coil segments at one or more metal layers of said integrated circuit without shorting to said primary coil.

9. The planar transformer of claim 1 wherein an outmost segment of said primary turn is electrically connected to an innermost segment of an adjacent primary turn, such that an electrical conductive path length of said outermost segment of said primary turn is approximately equal to an electrical conductive path length of said innermost segment of said primary turn.

10. The planar transformer of claim 9 wherein spiral turns of said secondary conductive paths are embedded after (i/2) segments of said primary coil, when said primary segments total an even number of segments, or wherein the spiral turns of said secondary conductive paths are embedded after (i/2+1) segments of said primary coil, when said primary segments total an odd number of segments.

11. The planar transformer of claim 4 wherein said conductive path segments of said secondary winding are electrically connected across metal layers to form series stacked spirals.

12. The planar transformer of claim 11 wherein said conductive path segments of said secondary winding are electrically connected in a spiral-in/spiral-out series configuration across metal layers.

13. The planar transformer of claim 11 wherein said conductive path segments of said secondary winding are electrically connected in a spiral-up/spiral-down series configuration.

14. The planar transformer of claim 12 including a low-K inter-layer dielectric to reduce capacitance between the series stacked spiral turns across metal layers.

15. The planar transformer of claim 12 wherein lower spirals of said secondary winding are vertically offset from upper spirals in order to reduce inter-layer capacitance.

16. The planar transformer of claim 13 wherein lower spirals of said secondary winding are vertically offset from upper spirals in order to reduce inter-layer capacitance.

17. A transformer for an integrated circuit, said transformer having an embedded coil structure comprising:
a primary winding or coil turn including at least two substantially parallel conductive path segments having a distance therebetween, wherein each of said at least two substantially parallel conductive path segments comprise stacked conductive path segments arranged in a top metal layer and a bottom metal layer; and
a secondary winding or coil turn comprising a secondary conductive path segment embedded between said two conductive paths of said primary coil, wherein said secondary conductive path segment comprises stacked conductive path segments arranged in said top metal layer and said bottom metal layer.

18. The transformer of claim 17 including magnetic material formed across layers to increase inductance density of said secondary winding.

19. The transformer of claim 17 wherein said primary and secondary windings form spiral turns.

20. The transformer of claim 19 wherein primary and secondary windings include changing width and spacing across spiral turns.

21. The transformer of claim 20 wherein said changing width and spacing are formed across various metal layers.

22. The transformer of claim 19 wherein a secondary to primary spiral turns ratio can be made greater than 1:1 by changing the number of secondary spirals at each metal layer.

23. The transformer of claim 19 including high-μ magnetic material across said spiral turns to increase inductance density.

24. The transformer of claim 19 including forming crisscross electrical connections across said spiral turns of both primary and secondary windings.

25. A method of making a transformer for an integrated circuit comprising forming a first metallization layer on a semiconductor substrate, said first metallization layer including at least a first primary winding or coil segment comprising two parallel conductive paths with a distance therebetween, and at least a corresponding first secondary winding or coil segment embedded between said two parallel conductive paths of said first primary coil segment.

26. The method of claim 25 including:
forming a second metallization layer on said semiconductor substrate including at least a second primary winding or coil segment having two parallel conductive paths with a distance therebetween, and at least a second corresponding secondary winding or coil segment embedded between said two parallel conductive paths of at least said secondary primary coil segment;
forming an electrically conductive overpass/underpass cross-over junction at the intersection of said first primary coil segment and said second primary coil segment; and
forming an electrically conductive overpass/underpass cross-over junction at the intersection of said first secondary coil segment and said second secondary coil segment.

27. The method of claim 25 wherein said first primary coil segments of said primary coil and said first secondary segments of said secondary coil are of constant width.

28. The method of claim 26 wherein said primary segments are designed wider than said embedded secondary segments to reduce series losses and increase current handling.

29. The method of claim 26 including forming some secondary segments to be electrically connected in an up-down manner from said first metallization layer to said second metallization layer while simultaneously embedded within each parallel conductive path of said primary coil.
